(19) United States
(12) Patent Application Publication
(10) Pub. No.: US 2025/0279393 A1
(43) Pub. Date: Sep. 4, 2025

(54) SEMICONDUCTOR DEVICE PRODUCTION METHOD AND STRUCTURE

(71) Applicant: Resonac Corporation, Minato-ku, Tokyo (JP)

(72) Inventors: Motoo AOYAMA, Minato-ku, Tokyo (JP); Keiichi HATAKEYAMA, Minato-ku, Tokyo (JP); Yuki IMAZU, Minato-ku, Tokyo (JP)

(21) Appl. No.: 18/859,550

(22) PCT Filed: Aug. 30, 2023
(86) PCT No.: PCT/JP2023/031628

§ 371 Date: Oct. 24, 2024

(30) Foreign Application Priority Data
Sep. 5, 2022 (WO) PCT/JP2022/033316

(51) Int. Cl. H01L 23/00

(52) U.S. Cl. CPC H01L 24/97; H01L 2224/97; H01L 2924/3512

(57) ABSTRACT

In this method for producing a semiconductor device, a structure 200 is prepared which includes an interposer 60 in which groove portions 61 divided into a plurality of installation regions 65 is formed and semiconductor elements 202a and 202b arranged on each of the installation regions 65. The semiconductor element 202a is a processor, and the semiconductor element 202a is a memory. Each groove portion 61 includes two parallel grooves 61a. In the structure 200, the semiconductor elements 202a and 202b are sealed such that the sealing material 80b enters each groove 61a. Then, the back surface of the interposer 60 is polished so that the sealing material 80b entering each groove 61a is exposed. Thereafter, the sealing material 80b is cut off along the groove portions 61 to acquire the plurality of semiconductor devices 201.

### TECHNICAL FIELD

The present disclosure relates to a method for producing semiconductor device and a structure.

### BACKGROUND ART

In response to the demand for higher functionality, various mounting methods for semiconductor elements have been developed. As an example, a 2.5D mounting is known in which a plurality of semiconductor elements are arranged close to each other on a silicon interposer, and the semiconductor elements are connected to each other via wiring formed in the silicon interposer (see, for example, Patent Literature 1).

A semiconductor device adopting such a mounting method using an interposer is manufactured through the following process. As an example, first, a plurality of semiconductor elements are disposed on an interposer, and each semiconductor element is connected to wiring formed in the interposer. Next, a sealing material is disposed on the interposer so as to cover the semiconductor element. Then, the sealing material and the interposer are cut off and individualized to obtain a plurality of semiconductor devices.

### CITATION LIST

### Patent Literature

Patent Literature 1: Japanese Unexamined Patent Publication No. 2018-037465

### SUMMARY OF INVENTION

### Technical Problem

In the process described above, for example, the interposer and the sealing material are sequentially cut off and individualized using a blade rotating at a high speed. Since the material of the interposer and the material of the sealing material are different from each other, it is necessary to cut off the interposer and the sealing material with different blades suitable for the respective materials. Therefore, for example, after the interposer is cut off using the blade for the interposer, the sealing material needs to be cut off after the blade is changed to the blade for the sealing material. The work of changing the blade at the time of such individualization becomes a cause of hindering improvement in production efficiency of the semiconductor device.

An object of the present disclosure is to provide a method for producing a semiconductor device and a structure capable of improving production efficiency of the semiconductor device.

### Solution to Problem

[1] The present disclosure relates to, as one aspect, a method for producing a semiconductor device. A method for producing the semiconductor device, the method includes preparing a structure including an interposer including a first main surface and a second main surface opposed to the first main surface, the interposer including a plurality of groove portions formed to divide the first main surface into a plurality of installation regions, and a plurality of semiconductor elements, at least one of the semiconductor elements being installed on each of the installation regions, wherein each of the groove portions includes at least two parallel grooves, sealing at least a part of each of the plurality of semiconductor elements with a sealing material such that the sealing material is disposed at least in the plurality of groove portions; polishing the interposer from the second main surface toward the first main surface such that the sealing material disposed in the plurality of groove portions is exposed; and individualizing the structure for each of the plurality of installation regions by cutting off the sealing material along each of the groove portions and acquiring a plurality of semiconductor devices.

In this producing method, a sealing material is disposed in a plurality of groove portions that divide the first main surface of the interposer into a plurality of installation regions, and the interposer is polished from the second main surface toward the first main surface such that the sealing material disposed in each groove portion is exposed. Then, a region including the sealing material disposed in each groove portion is cut off to individualize (chip) the structure, and a plurality of semiconductor devices are acquired. In this case, the structure can be individualized by cutting off the region including the sealing material disposed in the groove portion. Therefore, when the structure is individualized, for example, it is not necessary to use a blade for cutting off the interposer in addition to the blade for cutting off the sealing material. Thus, the production efficiency of the semiconductor device can be improved. Note that, in this producing method, a part of the interposer remains between at least two parallel grooves, but since the part of the interposer is not a part constituting the semiconductor device to be produced, there is no problem even if a blade for cutting off the interposer is not used. Further, when forming the groove portion in the interposer, if it is attempted to form a wide groove corresponding to the cutting-off width (blade width) at the time of individualization, it may take time to form the groove portion. However, according to the above producing method, the width of each groove in the groove portion can be narrowed to shorten the time required for forming the groove portion. Therefore, according to this producing method, the production efficiency of the semiconductor device can be improved also in this respect.

[2] In the method for producing the semiconductor device according to [1], the preparing the structure includes forming the plurality of groove portions having a depth of 10% to 60% with respect to a thickness of the interposer before being polished. When the depth of the groove portion to be formed is smaller than 10% of the thickness of the interposer before polishing, it is difficult to expose the sealing material in the polishing of the interposer. Further, in a case where the depth of the groove portion to be formed is larger than 60% of the thickness of the interposer before being polished, the strength of the interposer decreases, and there is a possibility that cracking occurs in the interposer in the producing process of the semiconductor device, and there is a possibility that the production efficiency decreases in order to prevent this cracking. On the other hand, according to the above producing method, the sealing material can be easily exposed in the step of polishing the interposer, and the interposer is hardly cracked in the producing process of the semiconductor device, so that the production efficiency is not reduced. Thus, the production efficiency of the semiconductor device can be improved.

[3] In the method for producing the semiconductor device according to [1] or [2], the preparing the structure includes forming the plurality of groove portions having a depth of 70 μm to 470 μm. In a case where the depth of the groove portion to be formed is smaller than 70 μm, it is difficult to expose the sealing material in the step of polishing the interposer. Further, in a case where the depth of the groove portion to be formed is larger than 470 μm, the strength of the interposer decreases, and there is a possibility that cracking occurs in the interposer in the producing process of the semiconductor device, and there is a possibility that the production efficiency decreases in order to prevent this cracking. On the other hand, according to the above producing method, the sealing material can be easily exposed in the step of polishing the interposer, and the interposer is hardly cracked in the producing process of the semiconductor device, so that the production efficiency is not reduced. Thus, the production efficiency of the semiconductor device can be improved.

[4] In the method for producing a semiconductor device of any one of [1] to [3], the width of each of the parallel grooves may be 20 μm to 50 μm. In this case, it is possible to reduce the amount of cutting chips or the like generated at the time of forming the groove portion and to prevent contamination from adhering to the semiconductor device including the semiconductor element. As a result, the defect rate in the individualized semiconductor device can be reduced, and the production efficiency of the semiconductor device can be further improved. Further, since the width of the parallel grooves is within the above range, for example, even in a case where the interposer is a silicon interposer, the parallel grooves can be quickly formed using the blade and the like for dicing an interposer.

[5] In the method for producing the semiconductor device according to any one of [1] to [4], the preparing the structure may include forming each of the groove portions such that a protruding portion remains between the parallel grooves, and in the acquiring the plurality of semiconductor devices, the sealing material and the protruding portion disposed in each of the groove portions may be collectively cut off. In this case, the step of forming the groove portion can be quickly performed, and the cutting-off at the time of individualization can also be quickly performed, so that the production efficiency of the semiconductor device can be further improved. Note that, in this case, the width of the protruding portion may be 100 μm to 200 μm. In this case, it is possible to more reliably perform cutting-off at the time of individualization.

[6] In the method for producing the semiconductor device according to any one of [1] to [5], the preparing of the structure may include forming a re-distribution layer on the first main surface before the plurality of groove portions are formed, removing an overlapping portion of the re-distribution layer with a portion where the plurality of groove portions are to be formed, and forming the plurality of groove portions in the interposer. In this case, in the re-distribution layer, the overlapping portion with the portion where the plurality of groove portions are to be formed is removed. As a result, for example, when a plurality of groove portions are formed in the interposer using the blade, the blade is less likely to come into contact with the re-distribution layer. As a result, peeling and chipping (minute deficiency) of the re-distribution layer can be suppressed.

[7] In the method for producing a semiconductor device according to [6], the material forming the re-distribution layer may include a material having photosensitivity. In the step of removing the overlapping portion, the overlapping portion may be removed by performing exposure and development on the re-distribution layer. In this case, even if the overlapping portion in the re-distribution layer has a complicated shape or a fine shape, the overlapping portion can be easily removed.

[8] The method for producing the semiconductor device according to any one of [1] to [7] may further include disposing an underfill between the plurality of semiconductor elements and the first main surface before the disposing the sealing material. In this case, for example, the semiconductor element is more stably fixed to the interposer by the underfill.

[9] In the method for producing a semiconductor device according to any one of [1] to [8], in the sealing, the sealing material may be disposed so as to cover a side surface and an upper surface of each of the semiconductor elements, and the method further may include polishing the sealing material such that the upper surface of each of the semiconductor elements is exposed from the sealing material. In this case, since the side surface of the semiconductor element is covered with the sealing material, the semiconductor element can be protected. Further, since the upper surface of the semiconductor element is exposed from the sealing material, heat dissipation of the semiconductor element can be improved. Note that, in this case, in the sealing, since the sealing material is also disposed in the plurality of groove portions of the interposer, the side surface of each portion of the individualized interposer is also covered with the sealing material. Accordingly, it is also possible to protect each portion of the interposer constituting the semiconductor device.

[10] In the method for producing the semiconductor device according to any one of [1] to [9], the preparing the structure may include simultaneously forming at least two parallel grooves by dicing the interposer using at least two first blades. In this case, the step of forming the groove parallel to the interposer can be performed more quickly, and the production efficiency of the semiconductor device can be further improved. Note that, in the above method for producing the semiconductor device, the preparing of the structure may include sequentially forming at least two parallel grooves by dicing the interposer using one first blade. In this case, the configuration of the blade device used for forming the groove can be simplified.

[11] In the method for producing the semiconductor device according to any one of [1] to [10], in the acquiring the plurality of semiconductor devices, the sealing material may be cut off along the groove portions using a second blade. In this case, the sealing material can be more reliably cut off.

[12] In the method for producing the semiconductor device according to [11], the preparing the structure may include forming a plurality of groove portions by dicing the interposer using the first blade. The grain size of the abrasive grains of the first blade may be larger than the grain size of the abrasive grains of the second blade. In this case, the groove portion can be more reliably formed in the interposer by using the first blade. Further, the groove portion formed in the interposer can be a groove having a fine cut surface. Furthermore, the interposer and the sealing material can be diced or cut off by the first blade and the second blade having abrasive grains suitable for the respective materials.

[13] In the method for producing the semiconductor device according to [12], the grain size of the abrasive grains of the first blade may be #2000 to #4000. The grain size of the abrasive grains of the second blade may be #320 to #600. In this case, the interposer and the sealing material can be diced or cut off by the first blade and the second blade having abrasive grains suitable for the respective materials.

[14] The present disclosure relates to a structure as another aspect. The structure includes an interposer including a first main surface and a second main surface opposed to the first main surface, and a plurality of semiconductor elements disposed on the first main surface. The interposer is formed with a plurality of groove portions that divide the first main surface into a plurality of installation regions. Each groove portion includes at least two parallel grooves. At least one of the plurality of semiconductor elements is disposed on each installation region. Note that, in the structure, two or more semiconductor elements may be disposed on each installation region.

In this structure, the interposer is formed with a plurality of groove portions that divide the first main surface into a plurality of installation regions. In a case where the semiconductor device is manufactured by the above-described producing method using this structure, the structure can be individualized by cutting off the sealing material disposed in the groove portion in the same manner as described above. Therefore, when the structure is individualized, for example, it is not necessary to use a blade for cutting off the interposer in addition to the blade for cutting off the sealing material. Thus, the production efficiency of the semiconductor device can be improved. Note that, in this structure, a part of the interposer remains between at least two parallel grooves, but since a part of the interposer is not a part constituting the semiconductor device to be produced, there is no problem even if a blade for cutting off the interposer is not used. Further, when forming the groove portion in the interposer, if it is attempted to form a wide groove corresponding to the cutting-off width at the time of individualization, it may take time to form the groove portion. However, according to the above structure, the width of each groove in the groove portion can be narrowed to shorten the time required for forming the groove portion. Therefore, according to this structure, the production efficiency of the semiconductor device can be improved also in this respect.

[15] In the structure according to [14], the plurality of groove portions may have a depth of 10% to 60% of a thickness of the interposer. In a case where the semiconductor device is manufactured by the above-described producing method using this structure, similarly to the above, the sealing material can be easily exposed in the step of polishing the interposer, and the interposer is hardly cracked in the producing process of the semiconductor device. Thus, the production efficiency of the semiconductor device can be improved.

[16] In the structure according to or [15], the plurality of groove portions may have a depth of 70 μm to 470 μm. In a case where the semiconductor device is manufactured by the above-described producing method using this structure, similarly to the above, the sealing material can be easily exposed in the step of polishing the interposer, and the interposer is hardly cracked in the producing process of the semiconductor device. Thus, the production efficiency of the semiconductor device can be improved.

[17] In the structure according to any one of [14] to [16], the width of each of the parallel grooves may be 20 μm to 50 μm. In this case, similarly to the above, it is possible to reduce the amount of cutting chips or the like generated at the time of forming the groove portion and to prevent contamination from adhering to the semiconductor device. As a result, the defect rate in the semiconductor device can be reduced, and the production efficiency of the semiconductor device can be further improved.

[18] In the structure according to any one of [14] to [17], a protruding portion may be provided between the parallel grooves, and a width of the protruding portion may be 100 μm to 200 μm. In this case, as described above, since the cutting-off at the time of individualization can be performed quickly, the production efficiency of the semiconductor device can be further enhanced.

[19] In the structure according to [14] to [18], the plurality of groove portions may be formed in a lattice shape including a plurality of first groove portions along the first direction and a plurality of second groove portions along the second direction intersecting the first direction. Each of the plurality of first groove portions may have at least two parallel grooves, and each of the plurality of second groove portions may have at least two parallel grooves. The interval between the first groove portions adjacent to each other may be 10 mm to 100 mm. The interval between the second groove portions adjacent to each other may be 20 mm to 100 mm. In a case where the semiconductor device is manufactured by the above-described producing method using this structure, the semiconductor device having a size that can be mounted on a general electronic component and having high versatility can be manufactured. Note that the interval between the groove portions here means an interval between adjacent grooves between a groove constituting one groove portion and a groove constituting another groove portion.

### Advantageous Effects of Invention

According to one aspect of the present disclosure, production efficiency of a semiconductor device can be improved.

### BRIEF DESCRIPTION OF DRAWINGS

FIG. 1 is a cross-sectional view schematically illustrating an example of a semiconductor device manufactured by a producing method according to a first embodiment.

FIG. 2 is a schematic cross-sectional view illustrating the method for producing the semiconductor device according to the first embodiment.

FIG. 3 is a schematic cross-sectional view illustrating the method for producing the semiconductor device according to the first embodiment.

FIG. 4 is a schematic cross-sectional view illustrating the method for producing the semiconductor device according to the first embodiment.

FIG. 5 is a plan view illustrating an interposer in which a groove portion is formed.

FIG. 6 is an enlarged plan view illustrating the groove portion of the interposer illustrated in FIG. 5.

FIG. 7 is a schematic cross-sectional view illustrating the method for producing the semiconductor device according to the first embodiment.

FIG. 8 is a schematic cross-sectional view illustrating the method for producing the semiconductor device according to the first embodiment.

FIG. 9 is a diagram illustrating a configuration of an underfill.

FIG. 10 is a schematic cross-sectional view illustrating the method for producing the semiconductor device according to the first embodiment.

FIG. 11 is a schematic cross-sectional view illustrating the method for producing the semiconductor device according to the first embodiment.

FIG. 12 is a schematic cross-sectional view illustrating the method for producing the semiconductor device according to the first embodiment.

FIG. 13 is a schematic cross-sectional view illustrating the method for producing the semiconductor device according to the first embodiment.

FIG. 14 is a cross-sectional view schematically illustrating an example of a semiconductor device manufactured by a producing method according to a second embodiment.

FIGS. 15A to 15C are schematic cross-sectional views illustrating the method for producing the semiconductor device according to the second embodiment.

FIGS. 16A to 16C are schematic cross-sectional views illustrating the method for producing the semiconductor device according to the second embodiment.

FIGS. 17A to 17C are schematic cross-sectional views illustrating the method for producing the semiconductor device according to the second embodiment.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description is omitted. Further, unless otherwise specified, the positional relationship such as up, down, left, and right is based on the positional relationship illustrated in the drawings. Furthermore, the dimensional ratios in the drawings are not limited to the illustrated ratios.

In the present specification, the numerical range indicated using “to” includes the numerical values described before and after “to” as the minimum value and the maximum value, respectively. In the numerical ranges described in stages in the present specification, the upper limit value or the lower limit value described in one numerical range may be replaced with the upper limit value or the lower limit value of the numerical range described in another stage. Further, in the numerical range described in the present specification, the upper limit value or the lower limit value of the numerical range may be replaced with a value shown in examples.

### First Embodiment

### (Configuration of Semiconductor Device)

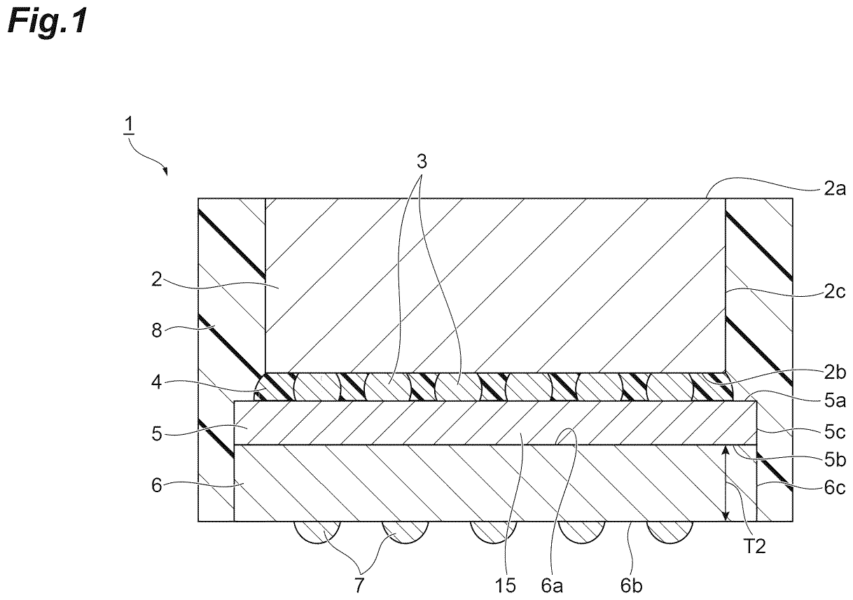

FIG. 1 is a cross-sectional view schematically illustrating an example of a semiconductor device 1 manufactured by a producing method according to the present embodiment. The semiconductor device 1 is, for example, a semiconductor package having a chip on wafer on substrate (CoWoS) structure. The semiconductor device 1 includes a semiconductor element 2, bumps 3, an underfill 4, a re-distribution layer 5, an interposer 6, bumps 7, and a sealing material 8. In CoWoS, the semiconductor device 1 having such a configuration is mounted on an organic substrate (not illustrated).

The semiconductor element 2 is, for example, a semiconductor chip such as a processor or a memory. The processor may be, for example, a processor unit such as a graphics processing unit (GPU) or a central processing unit (CPU). The memory may be, for example, a memory unit such as a high bandwidth memory (HBM). In the present embodiment, for convenience of explanation, a case where the semiconductor device 1 includes one semiconductor element 2 will be described as an example, but the semiconductor device 1 may include a plurality of semiconductor elements 2 (for example, refer to the second embodiment), and may include one processor and a plurality of memory units.

The semiconductor element 2 is disposed on the interposer 6 with the re-distribution layer 5 interposed therebetween. The semiconductor element 2 has an upper surface 2a, a lower surface 2b, and a side surface 2c connecting the upper surface 2a and the lower surface 2b. The upper surface 2a is located farther away from the interposer 6 than the lower surface 2b.

The bumps 3 are disposed between the semiconductor element 2 and the re-distribution layer 5 (RDL). The bumps 3 are disposed between the lower surface 2b of the semiconductor element 2 and a main surface 5a of the re-distribution layer 5 described later. The bumps 3 are formed of, for example, a metal material such as solder. The bumps 3 electrically connect the semiconductor element 2 and the re-distribution layer 5.

The underfill 4 is disposed between the semiconductor element 2 and the re-distribution layer 5 so as to cover the bumps 3. The underfill 4 is bonded to the semiconductor element 2 and the re-distribution layer 5. The underfill 4 seals and protects the bumps 3.

The re-distribution layer 5 is disposed between the bumps 3 and the interposer 6. The re-distribution layer 5 has main surfaces 5a and 5b that are opposite to each other, and a side surface 5c connecting the main surface 5a and the main surface 5b. The main surface 5a is located farther away from the interposer 6 than the main surface 5b. The bumps 3 and the underfill 4 are disposed on the main surface 5a. The re-distribution layer 5 is disposed directly on the interposer 6. The main surface 5b is in contact with the interposer 6. The re-distribution layer 5 includes a layered insulating portion 15 and wiring (not illustrated) formed in the insulating portion 15. The wiring electrically connects the bumps 3 and the interposer 6.

The interposer 6 is a substrate that supports the semiconductor element 2. In the present embodiment, the interposer 6 is formed in a rectangular plate shape. The shape of the interposer 6 is not limited, and the interposer 6 may be formed in a circular plate shape or a polygonal plate shape other than a rectangular shape. The interposer 6 includes main surfaces 6a and 6b that are opposite to each other, and a side surface 6c connecting the main surface 6a and the main surface 6b. The main surface 6a is in contact with the main surface 5b of the re-distribution layer 5. The interposer 6 is provided with wiring. The wiring may be a through electrode penetrating from the main surface 6a toward the main surface 6b. The wiring included in the interposer 6 electrically connects the wiring included in the re-distribution layer 5 and the bumps 7 to be described later. Note that, the side surface 6c of the interposer 6 is covered with the sealing material 8.

The bumps 7 are disposed on the main surface 6b of the interposer 6. The bumps 7 are formed of, for example, a metal material such as solder. The bumps 7 electrically connect the interposer 6 and another electronic component in a state where the semiconductor device 1 is mounted on the electronic component.

The sealing material 8 seals the semiconductor element 2 and the interposer 6. The sealing material 8 is annularly formed around the semiconductor element 2 when viewed from the thickness direction of the interposer 6. The sealing material 8 covers the side surface 2c of the semiconductor element 2, the surface of the underfill 4, the side surface 5c of the re-distribution layer 5, and the side surface 6c of the interposer 6. By being covered with the sealing material 8 in this manner, the durability of the semiconductor device 1 is enhanced. In particular, the interposer 6 may be formed of a material (for example, silicon) that is relatively hard and brittle. Even in this case, the interposer 6 can be more reliably protected by being covered with the sealing material 8. Further, the sealing material 8 does not cover the upper surface 2a of the semiconductor element 2 and the main surface 6b of the interposer 6. That is, the upper surface 2a and the main surface 6b are exposed from the sealing material 8. In the present embodiment, the entire upper surface 2a and the entire main surface 6b are exposed from the sealing material 8.

### (Method for Producing Semiconductor Device)

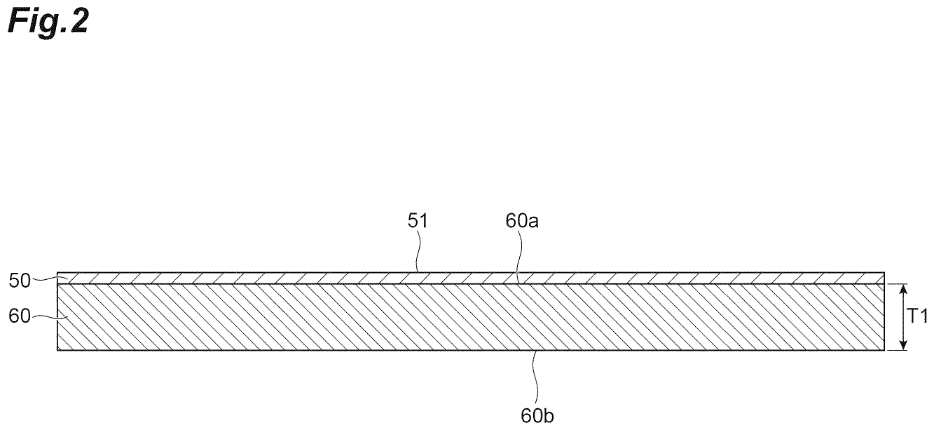

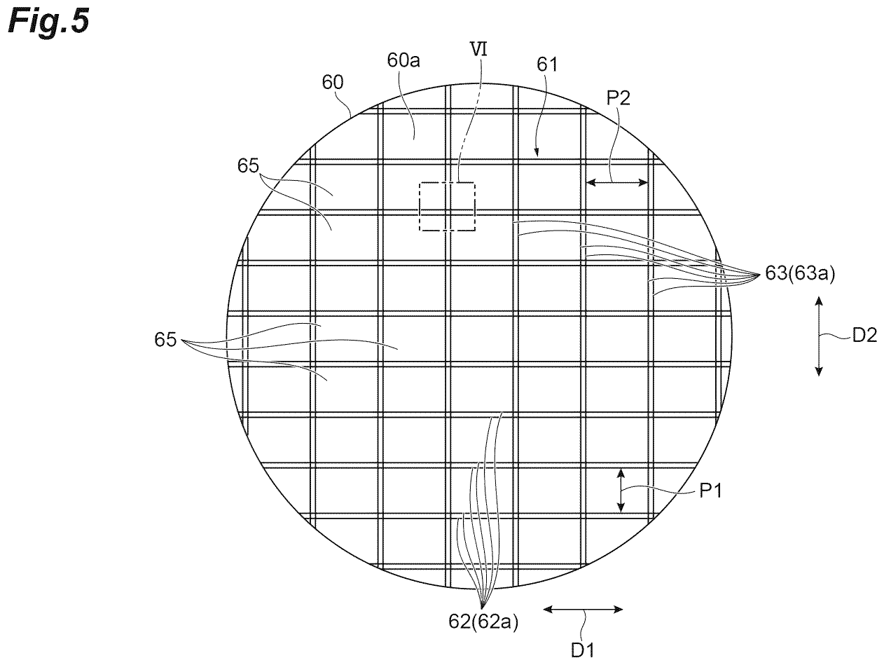

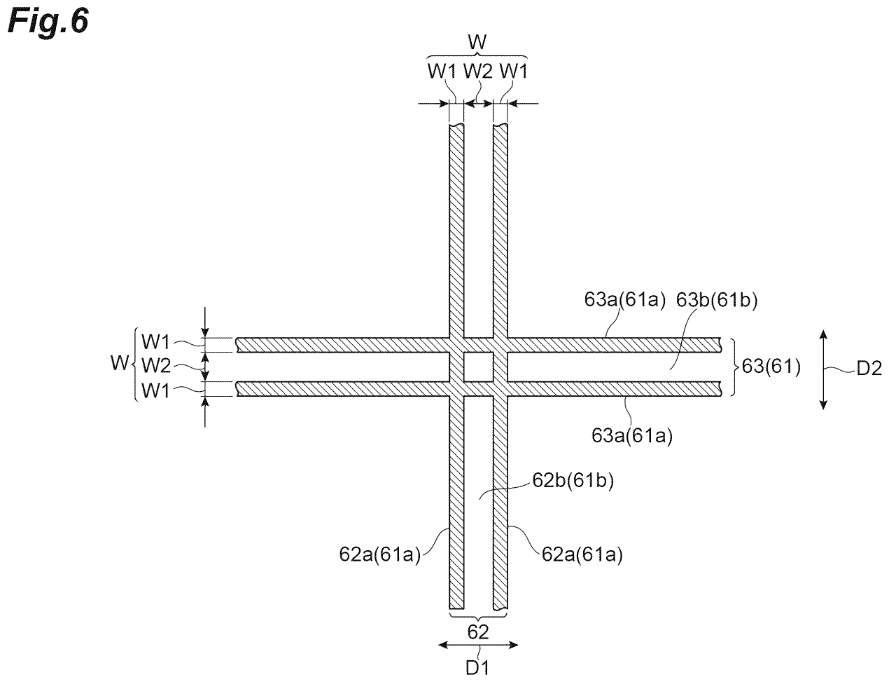

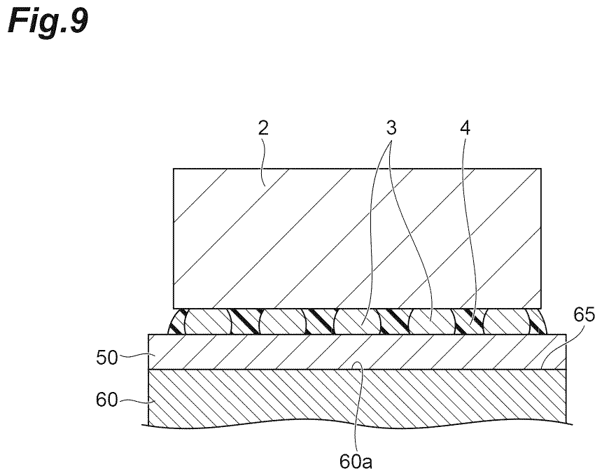

A method for producing the semiconductor device 1 will be described with reference to FIGS. 2 to 13. FIGS. 2 to 4, 7, 8, and 10 to 13 are schematic cross-sectional views illustrating the method for producing the semiconductor device 1. FIG. 5 is a plan view illustrating an interposer 60 in which a plurality of groove portions 61 are formed. FIG. 6 is an enlarged plan view illustrating the groove portion 61 (a first groove portion 62 and a second groove portion 63) of the interposer 60 illustrated in FIG. 5. FIG. 9 is a diagram illustrating a configuration of the underfill 4. The semiconductor device 1 is manufactured through, for example, the following steps (a) to (f).

(a) A step of preparing a structure 100 including: an interposer 60 including a main surface 60a (first main surface) and a main surface 60b (second main surface) opposite to the main surface 60a, and in which a plurality of groove portions 61 dividing the main surface 60a into a plurality of installation regions 65 are formed; and a plurality of semiconductor elements 2 disposed at least one by one on each installation region 65, in which each groove portion 61 includes at least two parallel grooves 61a.

(b) A step of disposing the underfill 4 between the plurality of semiconductor elements 2 and the main surface 60a.

(c) A step of sealing at least a part of each of the plurality of semiconductor elements 2 with a sealing material 80 such that a sealing material 80b is disposed in at least the groove portion 61 (groove 61a).

(d) A step of polishing the sealing material 80 such that the upper surface 2a of each semiconductor element 2 is exposed from the sealing material 80.

(e) A step of polishing the interposer 60 from the main surface 60b toward the main surface 60a so that the sealing material 80b disposed in the plurality of groove portions 61 is exposed.

(f) A step of individualizing the structure 100 for each of the plurality of installation regions 65 by cutting off the sealing material 80b along the groove portions 61 to acquire the plurality of semiconductor devices 1.

[Step (a)]

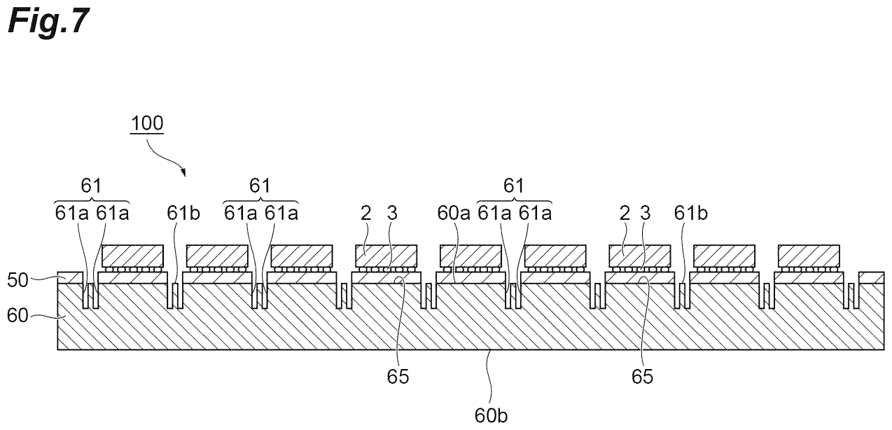

Step (a) will be described with reference to FIGS. 2 to 7. Step (a) is a step of preparing the structure 100 illustrated in FIG. 7. In step (a), first, as illustrated in FIG. 2, the interposer 60 is prepared. The interposer 60 is individualized in a later step to become the interposer 6 of the semiconductor device 1. The interposer 60 has a main surface 60a and a main surface 60b opposed to the main surface 60a. The direction in which the main surface 60a and the main surface 60b oppose each other is the thickness direction of the interposer 60. In the present embodiment, the interposer 60 is formed of silicon (Si). The interposer 60 has a circular plate shape. The interposer 60 may be formed of glass or an organic material, or may be an organic substrate formed using an organic material containing an inorganic filler. Such an organic substrate can be formed by, for example, laminating an interlayer insulating material (for example, an ABF film or the like) on a copper-clad laminate (for example, MCL series (product name, manufactured by Resonac Corporation)) that is a multilayer material as a core material. In a case where the interposer 60 is made of glass or an organic material, the interposer 60 may have a shape other than a circular plate shape (for example, a rectangular plate shape). The thickness T1 of the interposer 60 may be, for example, 500 μm to 1000 μm, or 700 μm to 800 μm. The interposer 60 is provided with wiring. The wiring may be a through-silicon via (TSV) penetrating from the main surface 60a toward the main surface 60b.

Next, a re-distribution layer 50 is formed on the main surface 60a of the interposer 60. The re-distribution layer 50 is individualized in a later step to become the re-distribution layer 5 of the semiconductor device 1. The re-distribution layer 50 is formed over the entire main surface 60a. The re-distribution layer 50 includes a layered insulating portion 51 and wiring (not illustrated) formed in the insulating portion 51. In the present embodiment, the insulating portion 51 is formed of an organic material. The organic material forming the insulating portion 51 may be a polyimide resin, a maleimide resin, an epoxy resin, a phenoxy resin, a polybenzoxal resin, an acrylic resin, or an acrylate resin. Note that, the insulating portion 51 of the re-distribution layer 50 may be formed using, for example, a photosensitive insulating material (for example, AH series (product name, manufactured by Resonac Corporation)).

The elastic modulus of the organic material is generally lower than the elastic modulus of the inorganic material. In other words, organic materials are generally softer than inorganic materials. The elastic modulus of the organic material forming the insulating portion 51 may be, for example, 1 GPa to 10 GPa. The elastic modulus here means Young's modulus.

The wiring included in the re-distribution layer 50 is formed of, for example, a metal material such as copper. The material forming the insulating portion 51 may have photosensitivity. In a case where the material for forming the insulating portion 51 has photosensitivity, a part of the insulating portion 51 may be removed by exposure and development, and a wiring may be formed on the removed portion by an electrolytic plating method or the like. Removal of the insulating portion 51 may be performed by laser irradiation. In the case of laser irradiation, the material forming the insulating portion 51 may not have photosensitivity. The wiring of the re-distribution layer 50 is electrically connected to the wiring of the interposer 60.

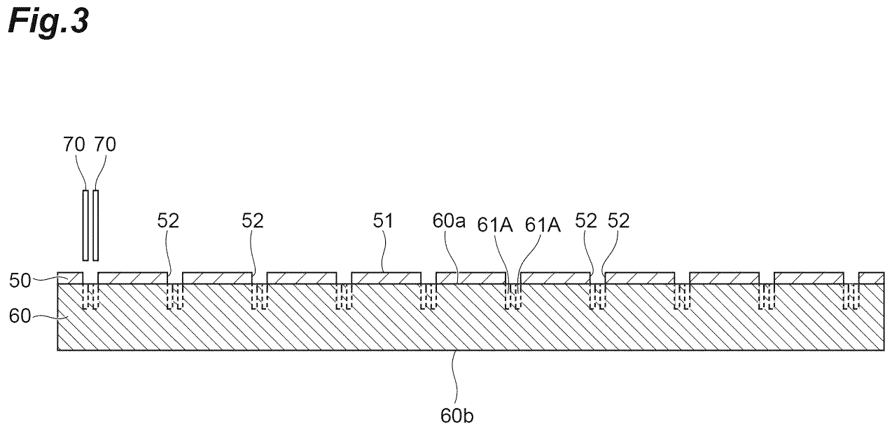

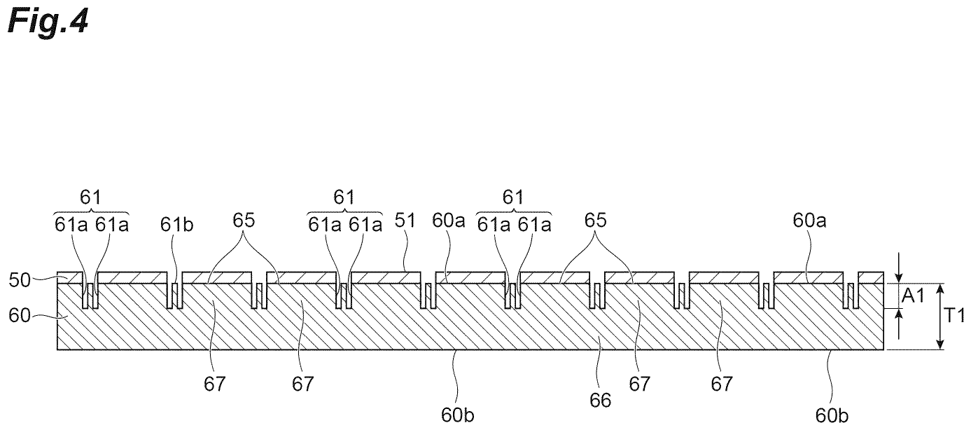

Next, as illustrated in FIG. 3, a part of the re-distribution layer 50 is removed. By removing a part of the re-distribution layer 50, a plurality of openings 52 are formed in the re-distribution layer 50. In the present embodiment, a plurality of groove portions 61 are formed in the interposer 60 after a part of the re-distribution layer 50 is removed (see FIG. 4). The detailed configuration of the groove portion 61 will be described later with reference to FIG. 4. In the step of removing a part of the re-distribution layer 50 illustrated in FIG. 3, portions of the re-distribution layer 50 corresponding to the plurality of groove portions 61 are removed. Each groove portion 61 is configured to have at least two grooves 61a. Specifically, in FIG. 3, a portion of the interposer 60 where the groove portion 61 (groove 61a) is to be formed is indicated by a two-dot chain line as a portion 61A. In the step of removing a part of the re-distribution layer 50 illustrated in FIG. 3, an overlapping portion of the re-distribution layer 50 with the portion 61A is removed. An overlapping portion with the portion 61A in the re-distribution layer 50 may be removed by performing exposure and development on the re-distribution layer 50, or may be removed by performing laser irradiation.

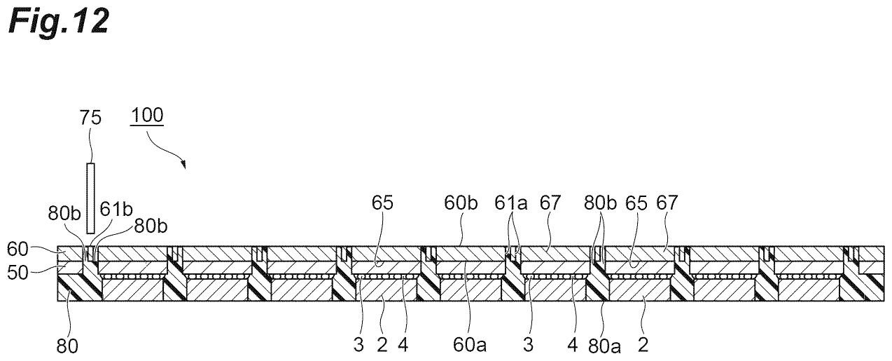

Next, as illustrated in FIG. 4, a plurality of groove portions 61 are formed in the interposer 60. The width W of each groove portion 61 corresponds to a cutting-off width (width of a blade 75) when the structure 100 is individualized in step (f) described later, and is preferably, for example, 100 μm to 500 μm (see FIG. 6). However, the width W of each groove portion does not need to coincide with the cutting-off width (that is, the blade width of the blade 75) at the time of individualization. The width W of each groove portion 61 is more preferably 150 μm to 400 μm, and still more preferably 200 μm to 300 μm. When the width W of each groove portion 61 is narrower than 100 μm, it becomes difficult to maintain the strength of the blade 75 (see FIG. 12) for dicing the sealing resin in step (f). On the other hand, when the width W of each groove portion 61 is larger than 500 μm, the region to be cut off is widened, and the number of semiconductor devices 1 that can be acquired from one interposer is reduced. Further, each groove portion 61 has two grooves 61a extending from the main surface 60a toward the main surface 60b of the interposer 60. The two grooves 61a extend in parallel with each other, and a protruding portion 61b is formed between the two grooves 61a. Each groove 61a constituting each groove portion 61 is formed in a slit shape and is opened in the main surface 60a. The depth A1 of the groove portion 61 (groove 61a) may be, for example, 70 μm to 470 μm, 100 μm to 400 μm, or 200 μm to 300 μm. The depth A1 of the groove portion 61 (groove 61a) with respect to the thickness T1 of the interposer 60 may be, for example, 10% to 60%, 20% to 50%, or 30% to 40%. The depth A1 of the groove portion 61 may be larger than the thickness T2 (see FIG. 1) of the interposer 6 of the semiconductor device 1 finally obtained by, for example, 30 μm to 50 μm. Further, the width W1 (see FIG. 6) of each groove 61a can be arbitrarily selected within the range of the width W, and may be, for example, 20 μm to 40 μm or 40 μm to 50 μm. The width W2 of the protruding portion 61b positioned between the grooves 61a may be, for example, 100 μm to 150 μm or 150 μm to 200 μm. Note that, the aspect ratio (depth A1:width W1) of the width W1 of the groove 61a to the depth A1 of the groove 61a may be, for example, 3.5:1 to 8:1.

Here, a more detailed configuration of the groove portion 61 will be described with reference to FIGS. 5 and 6. In FIGS. 5 and 6, for convenience of explanation, illustration of the re-distribution layer 50 is omitted, and only the interposer 60 is illustrated. As illustrated in FIGS. 5 and 6, the groove portion 61 includes a plurality of first groove portions 62 along a first direction D1 and a plurality of second groove portions 63 along a second direction D2 intersecting the first direction D1. That is, the groove portion 61 is formed in a lattice shape including the plurality of first groove portions 62 and the plurality of second groove portions 63. In the present embodiment, the second direction D2 is perpendicular to the first direction D1. Each of the first groove portions 62 has two parallel grooves 62a, and each of the second groove portions 63 has two parallel grooves 63a. A protruding portion 62b is formed between the two parallel grooves 62a, and a protruding portion 63b is formed between the two parallel grooves 63a. Further, an interval P1 between the first groove portions 62 adjacent to each other may be, for example, 10 mm to 100 mm or 25 mm to 60 mm. An interval P2 between the second groove portions 63 adjacent to each other may be, for example, 20 mm to 100 mm or 30 mm to 60 mm. The interval P2 may be larger than the interval P1.

The plurality of groove portions 61 divide the main surface 60a into a plurality of installation regions 65. In the present embodiment, each installation region 65 has a rectangular shape when viewed from the thickness direction of the interposer 60. The width of the installation region 65 along the first direction D1 is equal to the interval P2 between the second groove portions 63 adjacent to each other. The width of the installation region 65 along the second direction D2 is equal to the interval P1 between the first groove portions 62 adjacent to each other. The shape of each installation region 65 is not limited, and each installation region 65 may have, for example, a polygonal shape other than a rectangular shape. As illustrated in FIG. 4, the interposer 60 in which the groove portion 61 is formed includes a plate-shaped first portion 66 and a plurality of second portions 67 formed on the first portion 66. The second portion 67 has a mesa shape. The top surface of the second portion 67 corresponds to the installation region 65.

Each groove 61a (grooves 62a, 63a) of the groove portion 61 is formed using, for example, two blades 70 (first blade, see FIG. 3). As an example, by moving the two blades 70 rotating at a high speed from the main surface 60a toward the main surface 60b of the interposer 60 and dicing (machining) the interposer 60, two grooves 61a in each groove portion 61 are simultaneously formed. During this formation, the protruding portion 61b remains between the two grooves 61a. The two grooves 61a in each groove portion 61 may be formed in order using one blade 70. The blade 70 for dicing the interposer 60 is, for example, a dicing blade for dicing silicon, and forms the groove 61a, and thus has a blade width equivalent to the width W1 of the groove 61a. The blade width of the blade 70 is, for example, 20 μm to 50 μm. Further, the grain size (count) of the abrasive grains of the blade 70 for dicing the interposer 60 may be, for example, #2000 to #4000. The larger the # value indicating the grain size, the smaller the grain size of the abrasive grains. The abrasive grains may be diamond abrasive grains (SD). A method of forming each groove 61a of the groove portion 61 is not limited, and the groove portion 61 may be formed by laser irradiation, for example.

Next, as illustrated in FIG. 7, the semiconductor element 2 is installed on each installation region 65. In the present embodiment, one semiconductor element 2 is installed on each installation region 65. At least one semiconductor element 2 may be installed on each installation region 65. Therefore, a plurality of semiconductor elements 2 may be installed on each installation region 65. As an example, one processor (for example, GPU) and a plurality of memories (for example, HBM) may be installed on each installation region 65 as the plurality of semiconductor elements 2. In this case, in each installation region 65, the plurality of memories may be arranged close to the periphery of the processor. The processor and the memory may be arranged two-dimensionally without being stacked on each other. The plurality of memories may be stacked on each other and three-dimensionally arranged.

In the present embodiment, the re-distribution layer 50 is disposed on the interposer 60, and the semiconductor element 2 is installed on the re-distribution layer 50 via the bumps 3. That is, the semiconductor element 2 is installed on the installation region 65 via the re-distribution layer 50 and the bumps 3. The semiconductor element 2 is electrically connected to the wiring portion of the re-distribution layer 50 by the bumps 3. Through the above step (a), the structure 100 is prepared. The structure 100 to be prepared includes an interposer 60 and a plurality of semiconductor elements 2. The interposer 60 includes a main surface 60a and a main surface 60b opposed to the main surface 60a. The interposer 60 is formed with a plurality of groove portions 61 that divide the main surface 60a into a plurality of installation regions 65. Each groove portion 61 includes at least two parallel grooves 61a. At least one of the plurality of semiconductor elements 2 is installed on each installation region 65. In the present embodiment, the plurality of semiconductor elements 2 are installed one by one on each installation region 65.

[Step (b)]

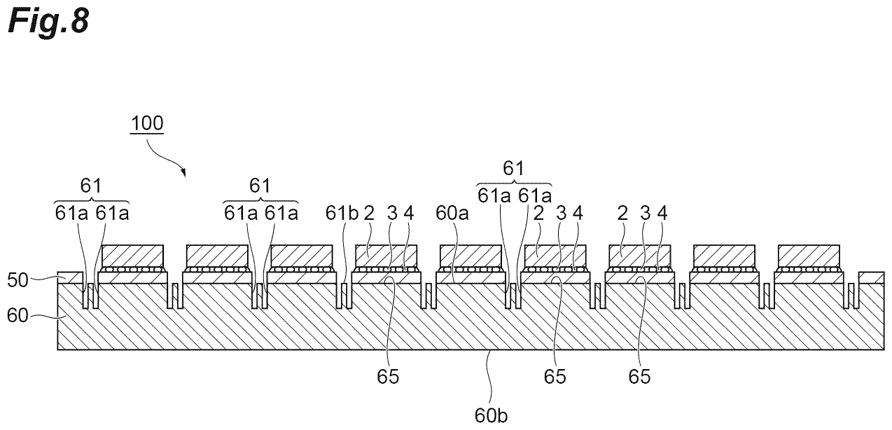

Step (b) is a step of disposing the underfill 4 between the plurality of semiconductor elements 2 and the main surface 60a of the interposer 60. As illustrated in FIG. 8, the underfill 4 is disposed between each semiconductor element 2 and the main surface 60a. In the present embodiment, the underfill 4 is disposed between the re-distribution layer 50 disposed on the main surface 60a and the semiconductor element 2. As illustrated in FIG. 9, the underfill 4 is disposed so as to cover the bumps 3 between the semiconductor element 2 and the re-distribution layer 50. The underfill 4 is filled in a gap between the bumps 3. The underfill 4 is bonded to the semiconductor element 2 and the re-distribution layer 50. The underfill 4 seals and protects the bumps 3. The underfill 4 may be formed of, for example, a material containing an epoxy resin. Note that, as the underfill 4, not only an individual underfill material may be used, but also a part of the sealing material 80 may be used as an underfill at the time of sealing with the sealing material 80 described later.

[Step (c)]

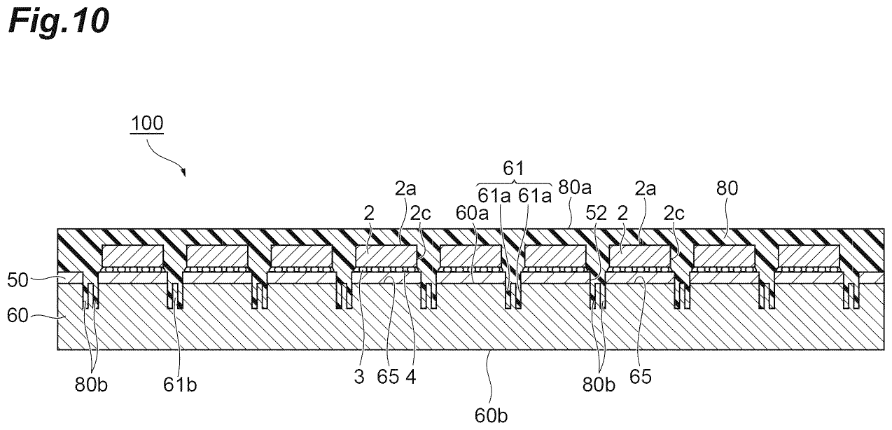

Step (c) is a step of sealing each of the plurality of semiconductor elements 2 with the sealing material 80 and disposing the sealing material 80b at least in the groove portion 61 (groove 61a). As illustrated in FIG. 10, the plurality of semiconductor elements 2 are sealed with the sealing material 80 such that the sealing material 80b is disposed (filled) over the entire groove portion 61. The sealing material 80 is also disposed inside the opening 52 of the re-distribution layer 50 and between the plurality of semiconductor elements 2. The sealing material 80 is disposed over the entire interposer 60 so as to cover the semiconductor element 2, the underfill 4, and the re-distribution layer 50. The sealing material 80 is disposed so as to cover the upper surface 2a and the side surface 2c of each semiconductor element 2. The sealing material 80 may be formed of, for example, a material containing an epoxy resin. The sealing material 80 may be an epoxy molding compound (EMC).

[Step (d)]

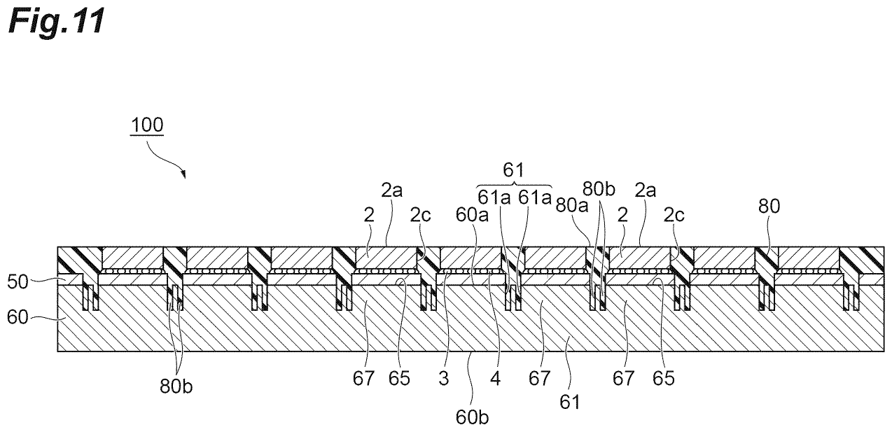

Step (d) is a step of polishing the sealing material 80 such that the upper surface 2a of each semiconductor element 2 is exposed from the sealing material 80. As illustrated in FIG. 10, the sealing material 80 has a surface 80a on a side opposite to the interposer 60. In step (d), the sealing material 80 is polished from the surface 80a toward the interposer 60, whereby the sealing material 80 is thinned. In the present embodiment, as illustrated in FIG. 11, the sealing material 80 is polished until the surface 80a is flush with the upper surface 2a. As a result, the upper surface 2a is exposed from the sealing material 80.

In the present embodiment, the direction of the interposer 60 is reversed after step (d) is completed. In the process up to step (d), the main surface 60a of the interposer 60 has been positioned above the main surface 60b in the vertical direction (see FIG. 11). On the other hand, in the process of step (e) and the subsequent steps, the interposer 60 is disposed such that the main surface 60a is positioned below the main surface 60b in the vertical direction.

[Step (e)]

Step (e) is a step of polishing the interposer 60 so that the sealing material 80b disposed in the two grooves 61a constituting each groove portion 61 is exposed. In step (e), the interposer 60 is polished from the main surface 60b toward the main surface 60a, whereby the interposer 60 is thinned. When the interposer 60 is polished until the sealing material 80b disposed in the groove portion 61 is exposed, the first portion 66 of the interposer 60 is removed and the plurality of second portions 67 remain as illustrated in FIGS. 11 and 12. When viewed from the thickness direction of the interposer 60, only the sealing material 80 and the protruding portion 61b between the grooves 61a exist between the adjacent second portions 67.

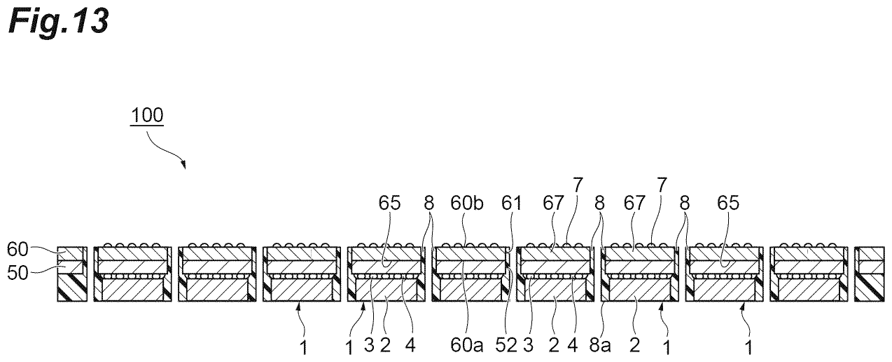

Next, as illustrated in FIG. 13, the bumps 7 are disposed on the interposer 60. In the present embodiment, the bumps 7 are disposed on the surface of each second portion 67 on a side opposite to the re-distribution layer 50. The bumps 7 are electrically connected to the wiring of the interposer 60.

[Step (f)]

Step (f) is a step of individualizing the structure 100 for each of the plurality of installation regions 65 by collectively cutting off the sealing material 80b in the two grooves 61a and the protruding portion 61b between the grooves 61a along each groove portion 61 to acquire the plurality of semiconductor devices 1. As illustrated in FIGS. 12 and 13, in step (f), the sealing material 80b and the protruding portion 61b are cut off in the thickness direction of the interposer 60. Specifically, the sealing material 80b disposed in the groove 61a in the sealing material 80, the protruding portion 61b between the grooves 61a, the sealing material 80 disposed in the opening 52 of the re-distribution layer 50 in the sealing material 80, and a portion disposed between the plurality of semiconductor elements 2 in the sealing material 80 are cut off together. As a result, the structure 100 is individualized for each of the plurality of installation regions 65. As described above, when viewed from the thickness direction of the interposer 60, the sealing materials 80 and 80b exist between the adjacent second portions 67. Therefore, when the sealing materials 80 and 80b are cut off in step (f), the main body portion (portion excluding the protruding portion 61b) of the interposer 60 is not cut off. In the present embodiment, the groove portions 61 are formed in a lattice shape when viewed from the thickness direction of the interposer 60. Therefore, the interposer 60 is cut off into a lattice shape along the groove portions 61.

The sealing material 80b, the protruding portion 61b, and the like in the groove 61a are cut off using, for example, a blade 75 (second blade). As an example, the sealing material 80b, the protruding portion 61b, and the like are cut off by the blade 75 rotating at a high speed. The blade 75 for cutting off the sealing material 80b and the like is, for example, a dicing blade for dicing the sealing material (resin material), and since the protruding portion 61b needs to be cut at least, it is preferable to have a blade width equal to or larger than the width W2 of the protruding portion 61b and equal to or smaller than the width W of the groove portion 61. The blade width of such a blade 75 is, for example, 100 μm to 200 μm. That is, the blade width of the blade 75 at the time of individualization may be wider than the blade width of the blade 70 (see FIG. 3) for dicing the groove 61a. In a case where the blade 75 having a blade width close to the width W2 of the protruding portion 61b is used, the thickness of the sealing material 80 on the side surface of the individualized semiconductor device 1 can be sufficiently secured, and the protective function of the package can be improved. Further, the grain size (count) of the abrasive grains of the blade 75 for cutting off the sealing material 80b and the like at the time of individualization may be, for example, #320 to #600. The abrasive grains may be diamond abrasive grains (SD). The grain size of the abrasive grains of the blade 70 (blade for forming the groove portion 61) for dicing the interposer 60 in step (a) may be larger than the grain size of the abrasive grains of the blade 75 for cutting off the sealing material 80b in step (f).

The structure 100 is individualized by step (f), and a plurality of semiconductor devices 1 (see FIG. 1) are acquired. The individualized interposer 60 corresponds to the interposer 6 of the semiconductor device 1, and the individualized re-distribution layer 50 corresponds to the re-distribution layer 5 of the semiconductor device 1. Thus, the producing process of the semiconductor device 1 is completed.

As described above, according to the method for producing the semiconductor device 1 of the present embodiment, the sealing material 80b is disposed in the plurality of groove portions 61 that divide the main surface 60a of the interposer 60 into the plurality of installation regions 65, and the interposer 60 is polished from the main surface 60b toward the main surface 60a so that the sealing material 80b disposed in each groove portion 61 is exposed. Then, a region including the sealing material 80b disposed in each groove portion 61 is cut off to individualize the structure 100, and a plurality of semiconductor devices 1 are acquired. In this case, the structure 100 can be individualized by cutting off the region including the sealing material 80b disposed in each groove portion 61 without cutting off the main body portion of the interposer 60. Therefore, when the structure 100 is individualized, for example, it is not necessary to use a blade for cutting off the interposer 60 in addition to the blade 75 for cutting off the sealing material 80b. As a result, for example, it is not necessary to replace the blade, and the production efficiency of the semiconductor device 1 can be improved. Further, in the conventional producing method in which it is necessary to sequentially cut off both the interposer and the sealing material when the structure is individualized, the interposer may be cut off so that the blade reaches the sealing material in order to reliably cut off the interposer. In this case, the blade for cutting off the interposer contacts the sealing material. As described above, in a case where an object made of a material different from the original object is cut off, abnormal wear may occur in the blade. On the other hand, in the method for producing the semiconductor device 1 according to the present embodiment, when the structure 100 is individualized, it is not necessary to bring the blade 75 for cutting off the region including the sealing material 80b into contact with the main body portion of the interposer 60, so that abnormal wear hardly occurs in the blade. As a result, the life of the blade is extended and the frequency of replacement of the blade is reduced, so that the production efficiency of the semiconductor device 1 can be improved. Furthermore, in the semiconductor device 1 manufactured by the producing method according to the present embodiment, since the side surface 6c of the interposer 6 is covered with the sealing material 8, the interposer 6 can be protected. According to the above configuration in which the side surface of the interposer 6 is covered with the sealing material 8, the interposer 6 can be more reliably protected even in a case where the interposer 6 is formed of silicon or the like having a relatively hard and brittle property. Further, in the above producing method, a part of the interposer remains between the two parallel grooves 61a. However, since a part of the interposer (protruding portion 61b) is not a portion constituting the semiconductor device 1 to be produced, there is no problem even if a blade for cutting off the interposer 60 is not used (that is, there is no problem even if cutting-off is collectively performed by the blades 75). Further, when forming the groove portion 61 in the interposer 60, if it is attempted to form a wide groove corresponding to the cutting-off width at the time of individualization, it may take time to form the groove portion. However, according to the above producing method, the width of each groove 61a in the groove portion can also be narrowed to shorten the time required for forming the groove portion 61. Therefore, according to this producing method, the production efficiency of the semiconductor device can be improved also in this respect.

In the method for producing the semiconductor device 1 of the present embodiment, the step of preparing the structure 100 may include a step of forming the groove portion 61 (groove 61a) having the depth A1 of 10% to 60% with respect to the thickness T1 of the interposer 60. In a case where the depth A1 of the groove portion 61 is smaller than 10% of the thickness T1 of the interposer 60, it is difficult to expose the sealing material 80b in the step of polishing the interposer 60. Further, in a case where the depth A1 of the groove portion 61 is larger than 60% of the thickness T1 of the interposer 60, the strength of the interposer 60 decreases, and there is a possibility that cracking occurs in the interposer 60 in the producing process of the semiconductor device 1, and there is a possibility that the production efficiency decreases in order to prevent this cracking. On the other hand, according to the above producing method, the sealing material 80b can be easily exposed in the step of polishing the interposer 60, and the interposer 60 is hardly cracked in the producing process of the semiconductor device 1, so that the production efficiency is not reduced. Thus, the production efficiency of the semiconductor device 1 can be improved.

In the method for producing the semiconductor device 1 of the present embodiment, the step of preparing the structure 100 may include a step of forming the groove portion 61 (groove 61a) having the depth A1 of 70 μm to 470 μm. In a case where the depth A1 of the groove portion 61 is smaller than 70 μm, it is difficult to expose the sealing material 80b in the step of polishing the interposer 60. Further, in a case where the depth A1 of the groove portion 61 is larger than 470 μm, the strength of the interposer 60 decreases, and there is a possibility that cracking occurs in the interposer 60 in the producing process of the semiconductor device 1, and there is a possibility that the production efficiency decreases in order to prevent this cracking. On the other hand, according to the above producing method, the sealing material 80b can be easily exposed in the step of polishing the interposer 60, and the interposer 60 is hardly cracked in the producing process of the semiconductor device 1, so that the production efficiency is not reduced. Thus, the production efficiency of the semiconductor device 1 can be improved.

In the method for producing the semiconductor device 1 of the present embodiment, the width of each of the parallel grooves 61a may be 20 μm to 50 μm. In this case, it is possible to reduce the amount of cutting chips or the like generated at the time of forming the groove portion 61 and to prevent contamination from adhering to the semiconductor device 1 including the semiconductor element 2. As a result, the defect rate in the individualized semiconductor device I can be reduced, and the production efficiency of the semiconductor device 1 can be further improved. Further, since the width of the parallel grooves 61a is within the above range, for example, even in a case where the interposer 60 is a silicon interposer, the parallel grooves 61a can be quickly formed using the blade 70 and the like.

In the method for producing the semiconductor device 1 of the present embodiment, the step of preparing the structure 100 includes a step of forming each groove portion 61 such that the protruding portion 61b remains between the parallel grooves 61a. Further, in the step of acquiring the plurality of semiconductor devices 1, the sealing material 80b and the protruding portion 61b disposed in the grooves 61a of each groove portion 61 are cut off together. In this case, the step of forming the groove portion 61 can be quickly performed, and the cutting-off at the time of individualization can also be quickly performed, so that the production efficiency of the semiconductor device 1 can be further improved. Note that, in this case, the width of the protruding portion 61b may be 100 μm to 200 μm. In this case, it is possible to more reliably perform cutting-off at the time of individualization.

In the method for producing the semiconductor device 1 of the present embodiment, the interposer 60 is formed of silicon (Si). In this case, the wiring formed in the interposer 60 can be miniaturized.

In the method for producing the semiconductor device 1 of the present embodiment, the step of preparing the structure 100 includes a step of forming the re-distribution layer 50 on the main surface 60a before the plurality of groove portions 61 are formed, a step of removing an overlapping portion of the re-distribution layer 50 with a portion (portion 61A) where the plurality of groove portions 61 are to be formed, and a step of forming the plurality of groove portions 61 in the interposer 60. In this case, in the re-distribution layer 50, the overlapping portion with the portion where the plurality of groove portions 61 are to be formed is removed. As a result, for example, when the groove portion 61 is formed in the interposer 60 using the blade, the blade is less likely to come into contact with the re-distribution layer 50. As a result, peeling and chipping (minute deficiency) of the re-distribution layer 50 can be suppressed.

In the method for producing the semiconductor device 1 of the present embodiment, the material forming the re-distribution layer 50 may include a material having photosensitivity. In the step of removing the overlapping portion, the overlapping portion may be removed by performing exposure and development on the re-distribution layer 50. In this case, even if the overlapping portion in the re-distribution layer 50 has a complicated shape or a fine shape, the overlapping portion can be easily removed.

The method for producing the semiconductor device 1 according to the present embodiment further includes a step of disposing the underfill 4 between the plurality of semiconductor elements 2 and the main surface 60a before the step of disposing the sealing material 80. In this case, the semiconductor element 2 is more stably fixed to the interposer 60 by the underfill 4.

In the method for producing the semiconductor device 1 according to the present embodiment, the step of disposing the sealing material 80 further includes a step of disposing the sealing material 80 so as to cover the side surface 2c and the upper surface 2a of each semiconductor element 2, and polishing the sealing material 80 so that the upper surface 2a of each semiconductor element 2 is exposed from the sealing material 80. In this case, since the side surface 2c of the semiconductor element 2 is covered with the sealing material 80, the semiconductor element 2 can be protected. Further, since the upper surface 2a of the semiconductor element 2 is exposed from the sealing material 8, heat dissipation of the semiconductor element 2 can be improved.

In the method for producing the semiconductor device 1 of the present embodiment, the step of preparing the structure 100 includes a step of simultaneously forming at least two parallel grooves 61a by dicing the interposer 60 using at least two blades 70. In this case, the step of forming the groove 61a parallel to the interposer can be performed more quickly, and the production efficiency of the semiconductor device 1 can be further improved.

In the method for producing the semiconductor device 1 of the present embodiment, in the step of acquiring the plurality of semiconductor devices 1, the region including the sealing material 80b is cut off along the groove portion 61 using the blade 75. In this case, the region including the sealing material 80b can be more reliably cut off.

In the method for producing the semiconductor device 1 of the present embodiment, the step of preparing the structure 100 includes a step of forming the plurality of groove portions 61 by dicing the interposer 60 using the blade 70. Further, the grain size of the abrasive grains of the blade 70 for dicing the interposer 60 in the step of forming the groove portion 61 is larger than the grain size of the abrasive grains of the blade 75 for cutting off the region including the sealing material 80b in the step of acquiring the plurality of semiconductor devices 1. In this case, the groove portion 61 can be more reliably formed with respect to the interposer 60 by using the blade 70. Further, the groove portion 61 formed in the interposer 60 can be a groove having a fine cut surface. Furthermore, the interposer 60 and the sealing material 80 can be diced or cut off by a blade having abrasive grains suitable for the respective materials.

In the method for producing the semiconductor device 1 of the present embodiment, the grain size of the abrasive grains of the blade 70 for dicing the interposer 60 in the step of forming the groove portion 61 may be #2000 to #4000. The grain size of the abrasive grains of the blade 75 for cutting off the sealing material 80b and the like in the step of acquiring the plurality of semiconductor devices 1 may be #320 to #600. In this case, the interposer 60 and the sealing material 80 can be diced or cut off by a blade having abrasive grains suitable for the respective materials.

In the structure 100 according to the present embodiment, the interposer 60 is formed with the plurality of groove portions 61 that divide the main surface 60a into the plurality of installation regions 65. In a case where the semiconductor device 1 is manufactured by the above-described producing method using the structure 100, the structure 100 can be individualized by cutting off the sealing material 80b and the like disposed in the groove portion 61 without cutting off the main body portion of the interposer 60 in the same manner as described above. Therefore, when the structure 100 is individualized, for example, it is not necessary to use a blade for cutting off the interposer 60 in addition to the blade 75 for cutting off the sealing material 80. Thus, the production efficiency of the semiconductor device 1 can be improved. Note that, in the structure 100, a part (protruding portion 61b) of the interposer 60 remains between the two parallel grooves 61a, but since a part of the interposer is not a part constituting the semiconductor device 1 to be produced, there is no problem even if a blade for cutting off the interposer 60 is not used at the time of individualization. Further, when forming the groove portion 61 in the interposer 60, if it is attempted to form a wide groove corresponding to the cutting-off width at the time of individualization, it may take time to form the groove portion 61. However, according to the structure 100, the width W1 of each groove 61a in the groove portion 61 can be narrowed to shorten the time required for forming the groove portion 61. Therefore, according to the structure 100, the production efficiency of the semiconductor device 1 can be improved also in this respect.

In the structure 100 of the present embodiment, each groove 61a of the plurality of groove portions 61 may have a depth A1 of 10% to 60% with respect to the thickness T1 of the interposer 60. In a case where the semiconductor device 1 is manufactured by the above-described producing method using the structure 100, similarly to the above, the sealing material 80 can be easily exposed in the step of polishing the interposer 60, and the interposer 60 is hardly cracked in the producing process of the semiconductor device 1. Thus, the production efficiency of the semiconductor device 1 can be improved.

In the structure 100 of the present embodiment, each groove 61a of the plurality of groove portions 61 may have a depth A1 of 70 μm to 470 μm. In a case where the semiconductor device 1 is manufactured by the above-described producing method using the structure 100, similarly to the above, the sealing material 80 can be easily exposed in the step of polishing the interposer 60, and the interposer 60 is hardly cracked in the producing process of the semiconductor device 1. Thus, the production efficiency of the semiconductor device 1 can be improved.

In the structure 100 of the present embodiment, the width of each of the parallel grooves 61a may be 20 μm to 50 μm. In this case, similarly to the above, it is possible to reduce the amount of cutting chips or the like generated at the time of forming the groove portion 61 and to prevent contamination from adhering to the semiconductor device 1. As a result, the defect rate in the semiconductor device 1 can be reduced, and the production efficiency of the semiconductor device 1 can be further improved.

In the structure 100 of the present embodiment, a protruding portion 61b may be provided between the parallel grooves 61a, and the width of the protruding portion 61b may be 100 μm to 200 μm. In this case, as described above, since the cutting-off at the time of individualization can be performed quickly, the production efficiency of the semiconductor device can be further enhanced.

In the structure 100 of the present embodiment, the plurality of groove portions 61 are formed in a lattice shape including the plurality of first groove portions 62 along the first direction D1 and the plurality of second groove portions 63 along the second direction D2 perpendicular to the first direction. Each of the plurality of first groove portions 62 may have two parallel grooves 62a, and each of the plurality of second groove portions 63 may have two parallel grooves 63a. The interval between the first groove portions 62 adjacent to each other may be 10 mm to 100 mm. The interval between the second groove portions 63 adjacent to each other may be 20 mm to 100 mm. In a case where the semiconductor device 1 is manufactured by the above-described producing method using the structure 100, the semiconductor device 1 having a size that can be mounted on a general electronic component and having high versatility can be manufactured.

### Second Embodiment

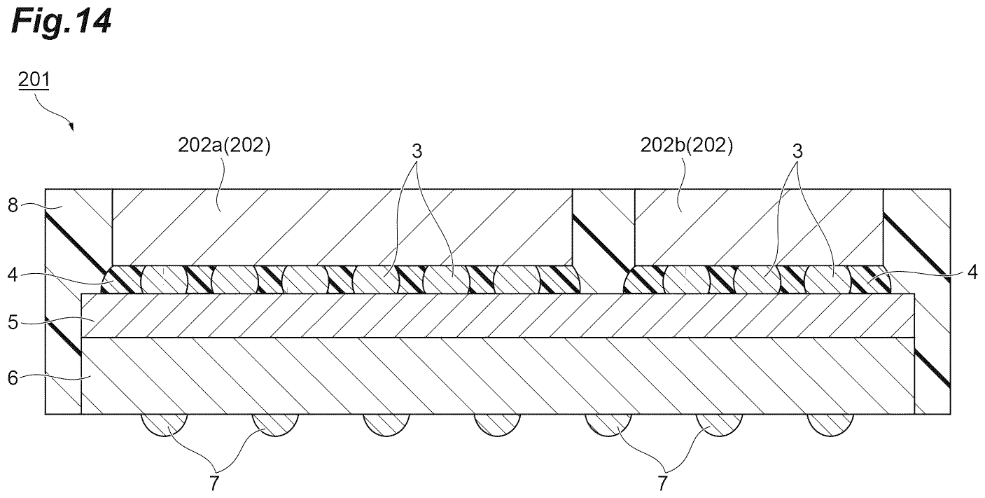

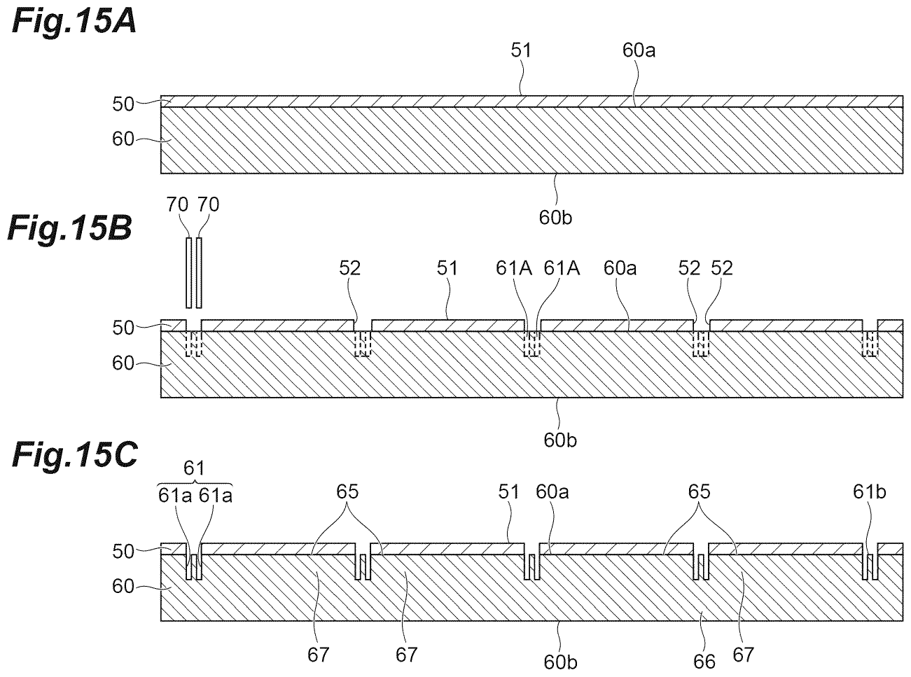

Next, a semiconductor device according to a second embodiment and a method for producing the same will be described with reference to FIGS. 14 to 17. FIG. 14 is a cross-sectional view schematically illustrating an example of a semiconductor device 201 manufactured by the producing method according to the second embodiment. FIGS. 15 to 17 are schematic cross-sectional views illustrating the method for producing the semiconductor device according to the second embodiment. The semiconductor device 201 according to the second embodiment is, for example, a semiconductor package having a chip on wafer on substrate (CoWoS) structure, and is different from the first embodiment in that a plurality of semiconductor elements are mounted on each semiconductor device. Since the other configurations are similar, the description thereof may be omitted below. As illustrated in FIG. 14, the semiconductor device 201 includes a plurality of semiconductor elements 202 (202a, 202b), bumps 3, underfills 4, a re-distribution layer 5, an interposer 6, bumps 7, and a sealing material 8.

The semiconductor element 202 is, for example, a semiconductor chip such as a processor or a memory. The processor may be, for example, a processor unit such as a graphics processing unit (GPU) or a central processing unit (CPU). The memory may be, for example, a memory unit such as a high bandwidth memory (HBM). In the example illustrated in FIG. 14, for example, one semiconductor element 202a is a processor unit, and the other semiconductor element 202b is a memory. The semiconductor element 202b may be a memory unit in which a plurality of memories are stacked. In the semiconductor device 201 according to the second embodiment, since the plurality of semiconductor elements 202 are provided, the sealing material 8 is configured to enter between the semiconductor elements 202. Further, the semiconductor elements 202a and 202b may be electrically connected to each other by the re-distribution layer 5 or a built-in chip or the like disposed in the re-distribution layer 5.

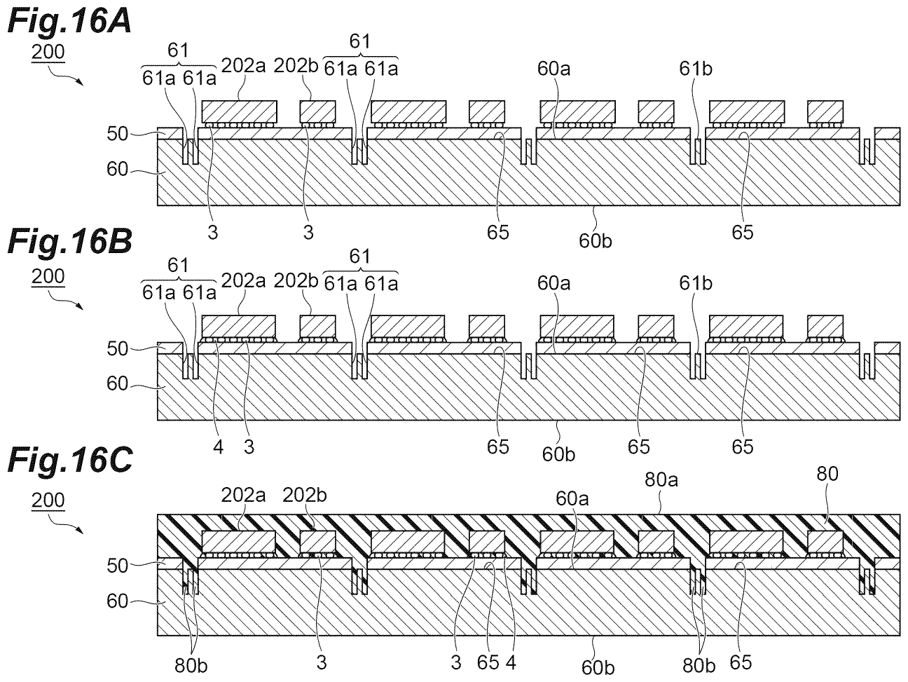

Next, a method for producing the semiconductor device 201 will be described with reference to FIGS. 15 to 17. Step (a) is a step of preparing a structure 200 illustrated in FIG. 16A. In step (a), first, as illustrated in FIG. 15A, the interposer 60 is prepared. The interposer 60 is individualized in a later step to become the interposer 6 of the semiconductor device 201. The re-distribution layer 50 is formed on the main surface 60a of the interposer 60. The re-distribution layer 50 is individualized in a later step to become the re-distribution layer 5 of the semiconductor device 201. The re-distribution layer 50 is formed over the entire main surface 60a. The re-distribution layer 50 includes a layered insulating portion 51 and wiring (not illustrated) formed in the insulating portion 51.

Next, as illustrated in FIG. 15B, a part of the re-distribution layer 50 is removed. By removing a part of the re-distribution layer 50, a plurality of openings 52 are formed in the re-distribution layer 50. In the present embodiment, after a part of the re-distribution layer 50 is removed, a plurality of groove portions 61 (at least two grooves 61a) are formed in the interposer 60 (see FIG. 15C). A method of removing a part of the re-distribution layer 50 is similar to that in the first embodiment.

Next, as illustrated in FIG. 15C, a plurality of groove portions 61 are formed in the interposer 60. Further, as in the first embodiment, each groove portion 61 has two grooves 61a extending from the main surface 60a to the main surface 60b of the interposer 60, the two grooves 61a extend in parallel with each other, and a protruding portion 61b is formed between the two grooves 61a. Each groove 61a constituting each groove portion 61 is formed in a slit shape and is opened in the main surface 60a. As in the first embodiment, the depth of the groove portion 61 (groove 61a) may be, for example, 70 μm to 470 μm, 100 μm to 400 μm, or 200 μm to 300 μm. The depth of the groove portion 61 (groove 61a) with respect to the thickness of the interposer 60 may be, for example, 10% to 60%, 20% to 50%, or 30% to 40%. The depth of the groove portion 61 may be larger than the thickness of the interposer 6 of the semiconductor device 201 finally obtained by, for example, 30 μm to 50 μm. The aspect ratio (depth: width) of the width of the groove 61a to the depth of the groove 61a may be, for example, 3.5:1 to 8:1.

Further, as in the first embodiment, the plurality of groove portions 61 divide the main surface 60a into a plurality of installation regions 65. When viewed from the thickness direction of the interposer 60, each installation region 65 has a rectangular shape. As illustrated in FIG. 15C, the interposer 60 in which the groove portion 61 is formed includes a plate-shaped first portion 66 and a plurality of second portions 67 formed on the first portion 66. The second portion 67 has a mesa shape. The top surface of the second portion 67 corresponds to the installation region 65. Note that, each groove 61a of the groove portion 61 is formed using, for example, two blades 70 as in the first embodiment.

Next, as illustrated in FIG. 16A, a plurality of semiconductor elements 202 are installed on each installation region 65. In the second embodiment, two semiconductor elements 202 are installed on each installation region 65. As an example, the semiconductor element 202a that is a processor (for example, GPU) and the semiconductor element 202b that is a memory (for example, HBM) are installed on each installation region 65. In a case where a plurality of memories are installed, the memories may be stacked and three-dimensionally arranged.

[Step (b)]

Step (b) is a step of arranging the underfill 4 between each of the semiconductor elements 202a and 202b and the re-distribution layer 50 as illustrated in FIG. 16B.

[Step (c)]

Step (c) is a step of sealing each of semiconductor elements 202a and 202b with the sealing material 80, and disposing the sealing material 80b at least in the groove portion 61 (each groove 61a). As illustrated in FIG. 16C, the plurality of semiconductor elements 202a and 202b are sealed with the sealing material 80 such that the sealing material 80b is disposed (filled) over the entire groove portion 61. The sealing material 80 is also disposed inside the opening 52 of the re-distribution layer 50 and between the semiconductor elements 202a and 202b. The sealing material 80 is disposed over the entire interposer 60 so as to cover the semiconductor elements 202a and 202b, the underfill 4, and the re-distribution layer 50. The sealing material 80 is disposed so as to cover the upper surface and the side surface of each semiconductor elements 202a and 202b.

[Step (d)]

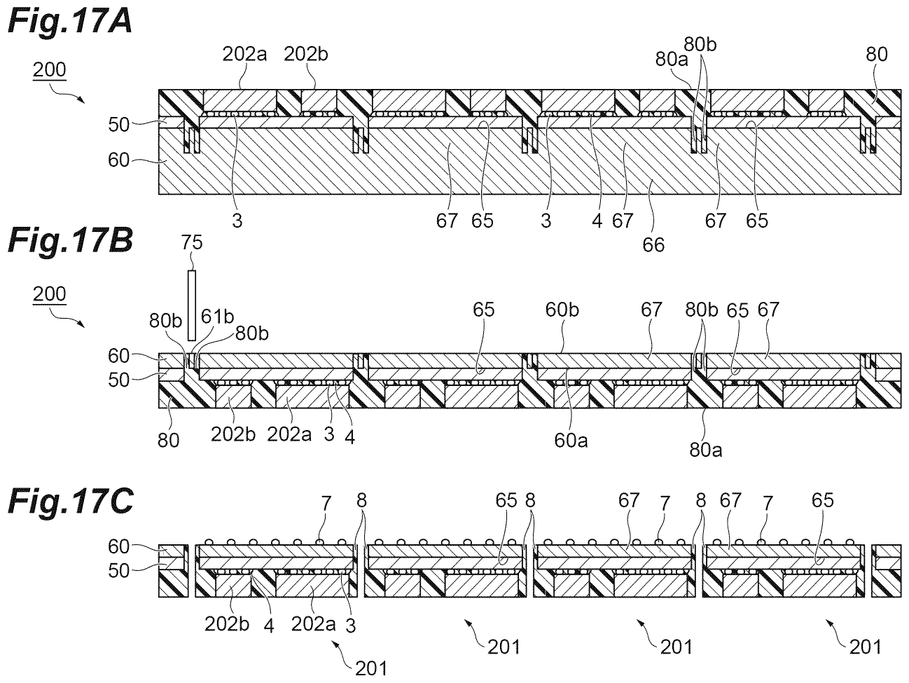

Step (d) is a step of polishing the sealing material 80 such that the upper surfaces of semiconductor elements 202a and 202b are exposed from the sealing material 80. As illustrated in FIG. 17A, the sealing material 80 has a surface 80a on a side opposite to the interposer 60. In step (d), the sealing material 80 is polished from the surface 80a toward the interposer 60, whereby the sealing material 80 is thinned. In the present embodiment, as illustrated in FIG. 17A, the sealing material 80 is polished until the surface 80a is flush with the upper surfaces of the semiconductor elements 202a and 202b. As a result, the upper surfaces of the semiconductor elements 202a and 202b are exposed from the sealing material 80.

In the present embodiment, the direction of the interposer 60 is reversed after step (d) is completed. In the process up to step (d), the main surface 60a of the interposer 60 has been positioned above the main surface 60b in the vertical direction (see FIG. 17A). On the other hand, in the process of step (e) and the subsequent steps, the interposer 60 is disposed such that the main surface 60a is positioned below the main surface 60b in the vertical direction.

[Step (e)]

Step (e) is a step of polishing the interposer 60 so that the sealing material 80b disposed in the two grooves 61a constituting each groove portion 61 is exposed. In step (e), the interposer 60 is polished from the main surface 60b toward the main surface 60a, whereby the interposer 60 is thinned. When the interposer 60 is polished until the sealing material 80b disposed in the groove portion 61 is exposed, the first portion 66 of the interposer 60 is removed and the plurality of second portions 67 remain as illustrated in FIG. 17B. When viewed from the thickness direction of the interposer 60, only the sealing material 80 (80b) and the protruding portion 61b between the grooves 61a exist between the adjacent second portions 67.

Next, as illustrated in FIG. 17C the bumps 7 are disposed on the interposer 60. In the present embodiment, the bumps 7 are disposed on the surface of each second portion 67 on a side opposite to the re-distribution layer 50. The bumps 7 are electrically connected to the wiring of the interposer 60.

[Step (f)]

As in the first embodiment, step (f) is a step of individualizing the structure 200 for each of the plurality of installation regions 65 by collectively cutting off the sealing material 80b in the two grooves 61a and the protruding portion 61b between the grooves 61a along each groove portion 61 to acquire the plurality of semiconductor devices 201. As illustrated in FIGS. 17B and 17C, in step (f), the sealing material 80b and the protruding portion 61b are cut off by the blade 75 in the thickness direction of the interposer 60. Specifically, the sealing material 80b disposed in the groove 61a in the sealing material 80, the protruding portion 61b between the grooves 61a, the sealing material 80 disposed in the opening 52 of the re-distribution layer 50 in the sealing material 80, and a portion disposed between the plurality of semiconductor elements 2 in the sealing material 80 are cut off together. As a result, the structure 200 is individualized for each of the plurality of installation regions 65. As described above, when viewed from the thickness direction of the interposer 60, the sealing materials 80 and 80b exist between the adjacent second portions 67. Therefore, when the sealing materials 80 and 80b are cut off in step (f), the main body portion (portion excluding the protruding portion 61b) of the interposer 60 is not cut off. Note that, the sealing material 80b, the protruding portion 61b, and the like in the groove 61a are cut off using, for example, a dicing blade rotating at a high speed. As a result, the structure 200 is individualized, and a plurality of semiconductor devices 201 (see FIG. 14) are acquired. The individualized interposer 60 corresponds to the interposer 6 of the semiconductor device 201, and the individualized re-distribution layer 50 corresponds to the re-distribution layer 5 of the semiconductor device 201. Thus, the producing process of the semiconductor device 201 is completed.

As described above, according to the method for producing the semiconductor device 201 of the second embodiment, as in the first embodiment, it is possible to individualize the structure 200 by cutting off the region including the sealing material 80b disposed in each groove portion 61 without cutting off the main body portion of the interposer 60. Therefore, when the structure 200 is individualized, for example, it is not necessary to use a blade for cutting off the interposer 60 in addition to the blade for cutting off the sealing material 80b. As a result, for example, it is not necessary to replace the blade, and the production efficiency of the semiconductor device 201 can be improved. Other effects similar to those of the first embodiment can be obtained.

Although the embodiments of the present disclosure have been described in detail above, the present disclosure is not limited to the above embodiments.

The insulating portion 51 of the re-distribution layer 50 may be formed of an inorganic material. The inorganic material forming the insulating portion 51 may be silicon dioxide (SiO₂), silicon nitride (SiN), or silicon oxynitride (SiON). In a case where the insulating portion 51 is formed of an inorganic material, when the overlapping portion with the portion 61A in the re-distribution layer 50 is removed in step (a) (see FIG. 3), the re-distribution layer 50 may be diced by a blade to remove the overlapping portion. The removal of the overlapping portion in the re-distribution layer 50 and the formation of the groove portion 61 (see FIG. 4) may be performed together using the same blade.

In step (a) of preparing the structures 100 and 200, each groove portion 61 may be formed of more than two parallel grooves 61a, for example, may be formed of three parallel grooves 61a.

In the producing process of the semiconductor devices 1 and 201, step (b) may be omitted. That is, the underfill 4 may not be disposed between the plurality of semiconductor elements 2 and 202 and the main surface 60a.

In the producing process of the semiconductor devices 1 and 201, step (d) may be omitted. That is, the sealing material 80 may not be polished and thinned so that the upper surface 2a of each of the semiconductor elements 2 and 202 is exposed from the sealing material 80. Specifically, the sealing material 80 may not be polished at all, or may be polished to such an extent that the upper surfaces 2a of the semiconductor elements 2 and 202 are not exposed from the sealing material 80.

The depth A1 of the groove portion 61 (groove 61a) formed in the interposer 60 is not limited. The depth A1 may be less than 10% relative to the thickness T1 of the interposer 60 or greater than 60% relative to the thickness T1. The depth A1 may be smaller than 70 μm or larger than 470 μm.

The orientations of the semiconductor devices 1 and 201 when the semiconductor devices 1 and 201 are mounted on another electronic component are not limited. That is, the semiconductor device 1 may be mounted such that the upper surfaces 2a of the semiconductor elements 2 and 202 are positioned above the lower surface 2b in the vertical direction, or the semiconductor devices 1 and 201 may be mounted such that the upper surface 2a is positioned below the lower surface 2b in the vertical direction.

### REFERENCE SIGNS LIST

1, 201 semiconductor device
2, 202, 202a, 202b semiconductor element
2a upper surface
2c side surface
3 bump
4 underfill
5, 50 re-distribution layer
6, 60 interposer
8, 80, 80b sealing material
60a main surface (first main surface)
60b main surface (second main surface)
61 groove portion
61A portion (portion to be formed)
61a groove
61b protruding portion
62 first groove portion
62a groove
62b protruding portion
63 second groove portion
63a groove
63b protruding portion
65 installation region
70 blade (first blade)
75 blade (second blade)
100, 200 structure

1. A method for producing a semiconductor device, the method comprising:
preparing a structure including an interposer including a first main surface and a second main surface opposed to the first main surface, the interposer including a plurality of groove portions formed to divide the first main surface into a plurality of installation regions, and a plurality of semiconductor elements, at least one of the semiconductor elements being installed on each of the installation regions, wherein each of the groove portions includes at least two parallel grooves;
sealing at least a part of each of the plurality of semiconductor elements with a sealing material such that the sealing material is disposed at least in the plurality of groove portions;
polishing the interposer from the second main surface toward the first main surface such that the sealing material disposed in the plurality of groove portions is exposed; and
individualizing the structure for each of the plurality of installation regions by cutting off the sealing material along each of the groove portions and acquiring a plurality of semiconductor devices.

2. The method for producing a semiconductor device according to claim 1, wherein the preparing the structure includes forming the plurality of groove portions having a depth of 10% to 60% with respect to a thickness of the interposer before being polished.

3. The method for producing a semiconductor device according to claim 1, wherein the preparing the structure includes forming the plurality of groove portions having a depth of 70 μm to 470 μm.

4. The method for producing a semiconductor device according to claim 1, wherein a width of each of the parallel grooves is 20 μm to 50 μm.

5. The method for producing a semiconductor device according to claim 1,
wherein the preparing the structure includes forming each of the groove portions such that a protruding portion remains between the parallel grooves, and
wherein in the acquiring the plurality of semiconductor devices, the sealing material and the protruding portion disposed in each of the groove portions are collectively cut off.

6. The method for producing a semiconductor device according to claim 5, wherein a width of the protruding portion is 100 μm to 200 μm.

7. The method for producing a semiconductor device according to claim 1, wherein the preparing the structure includes:
forming a re-distribution layer on the first main surface before the plurality of groove portions are formed;
removing an overlapping portion of the re-distribution layer with a portion where the plurality of groove portions are to be formed; and
forming the plurality of groove portions in the interposer.

8. The method for producing a semiconductor device according to claim 7,
wherein a material forming the re-distribution layer includes a material having photosensitivity, and
wherein in the removing the overlapping portion, the overlapping portion is removed by performing exposure and development on the re-distribution layer.

9. The method for producing a semiconductor device according to claim 1, further comprising:
disposing an underfill between the plurality of semiconductor elements and the first main surface before the disposing the sealing material.

10. The method for producing a semiconductor device according to claim 1,
wherein in the sealing, the sealing material is disposed so as to cover a side surface and an upper surface of each of the semiconductor elements, and
wherein the method further comprises polishing the sealing material such that the upper surface of each of the semiconductor elements is exposed from the sealing material.

11. The method for producing a semiconductor device according to claim 1, wherein the preparing the structure includes simultaneously forming the at least two parallel grooves by dicing the interposer using at least two first blades, or sequentially forming the at least two parallel grooves by dicing the interposer using one first blade.

12. The method for producing a semiconductor device according to claim 1, wherein in the acquiring the plurality of semiconductor devices, the sealing material is cut off along the groove portions using a second blade.

13. The method for producing a semiconductor device according to claim 12,
wherein the preparing the structure includes forming the plurality of groove portions by dicing the interposer using a first blade, and
wherein a grain size of an abrasive grain of the first blade is larger than a grain size of an abrasive grain of the second blade.

14. The method for producing a semiconductor device according to claim 13,
wherein the grain size of the abrasive grain of the first blade is #2000 to #4000, and
wherein the grain size of the abrasive grain of the second blade is #320 to #600.

15. A structure comprising:
an interposer including a first main surface and a second main surface opposed to the first main surface; and
a plurality of semiconductor elements disposed on the first main surface,
wherein the interposer includes a plurality of groove portions configured to divide the first main surface into a plurality of installation regions,
wherein each of the groove portions includes at least two parallel grooves, and
wherein at least one of the plurality of semiconductor elements is disposed on each of the installation regions.

16. The structure according to claim 15, wherein the plurality of groove portions have a depth of 10% to 60% of a thickness of the interposer.

17. The structure according to claim 15, wherein the plurality of groove portions have a depth of 70 μm to 470 μm.

18. The structure according to claim 15, wherein a width of each of the parallel grooves is 20 μm to 50 μm.

19. The structure according to claim 15,
wherein a protruding portion is provided between the parallel grooves, and
wherein a width of the protruding portion is 100 μm to 200 μm.

20. The structure according to claim 15,
wherein the plurality of groove portions are formed in a lattice shape including a plurality of first groove portions along a first direction and a plurality of second groove portions along a second direction intersecting the first direction,
wherein each of the plurality of first groove portions has at least two parallel grooves, and each of the plurality of second groove portions has at least two parallel grooves,
wherein an interval between the first groove portions adjacent to each other is 10 mm to 100 mm, and
wherein an interval between the second groove portions adjacent to each other is 20 mm to 100 mm.
